(19) United States
(12) Patent Application Publication
(10) Pub. No.: US 2007/0290333 A1
(43) Pub. Date: Dec. 20, 2007

(54) Chip stack with a higher power chip on the outside of the stack

(75) Inventors: Manish Saini, Hillsboro, OR (US); Deepa S. Mehta, Portland, OR (US)

Correspondence Address: BLAKELY SOKOLOFF TAYLOR & ZAFMAN, 1279 OAKMEAD PARKWAY, SUNNYVALE, CA, 94085-4040, US

(73) Assignee: Intel Corporation

(21) Appl. No.: 11/454,422

(22) Filed: Jun. 16, 2006

(51) Int. Cl. H01L 23/34

(52) U.S. Cl. 257/723

(57) ABSTRACT

In some embodiments, a system includes a circuit board, a first chip, and a second chip stacked on the first chip. The first chip is coupled between the circuit board and the second chip, and the first chip includes circuitry to repeats commands the first chip receives to the second chip. Other embodiments are described.

### BACKGROUND

1. Technical Field

Chip stacks are described in which higher power chips are positioned in locations with greater heat dissipation abilities.

2. Background Art

Various arrangements for memory chips in a memory system have been proposed. For example, in a traditional synchronous dynamic random access memory (DRAM) system, memory chips communicate data through multi-drop bidirectional data buses and receive commands and addresses through command and addresses buses. More recently, bidirectional or unidirectional point-to-point interconnects have been proposed.

In some systems, chips (also called dies) are stacked one on top of another. The chips may be all of the same type or some of the chips may be different than others. For example, a stack of memory chips (e.g., flash or DRAM) may be supported by a module substrate. A stack may include a chip with a memory controller. A stack may include a processor chip (with or without a memory controller) and a voltage regulator (VR) chip and perhaps other chips. A stack of chips may be on one side of a printed circuit board (PCB) substrate and a chip or another stack of chips may be on the other side of the substrate. For example, a processor may be on one side of the substrate and a VR chip may be on the other side of the substrate. The VR chip and/or the processor chip may be part of a stack. A heat sink may be included on, for example, the processor chip. One or more other heat sinks may also be used.

Various packaging techniques have been used to stack one chip on top of another. For example, a stack and substrate may include the following components in order: a package substrate, a die attach material layer, a chip, a die attach material layer, a chip, a die attach material layer, a chip, etc., with wire bond conductors between the chips and the package substrate. The wire bond wires may be in the die attach material. Solder balls may be between the package substrate and another substrate. As another example, solder balls could be between package substrate layers and/or redistribution layers, with chips being supported by the package substrate layers and/or redistribution layers. Wire bonds may be used in this example as well. A flip-chip technique may be used. Through silicon vias may be used. A package mold may surround multiple chips or each chip may have its own package. Various other packaging techniques have been used. Various heat dissipation techniques (for example, fans, heat sinks, liquid cooling, etc.) have been developed.

Some systems have been proposed in which chips (such as memory chips) repeat signals received by them to other chips.

Many chips operate with higher performance in a particular temperature range. If the temperature becomes too high, the chips may malfunction. Throttling techniques have been developed to reduce the voltage and frequency of a chip to reduce the temperature. However, with a lower frequency and voltage, the performance of the chip can also decrease. Accordingly, once the temperature of the chip is low enough, the voltage and frequency may be increased. Ideally, the temperature of a chip would always remain low enough so that the voltage and frequency would not have to be reduced.

Memory modules include a substrate on which memory chips are placed. The memory chips may be placed on only one side of the substrate or on both sides of the substrate. In some systems, a buffer is also placed on the substrate. For at least some signals, the buffer interfaces between the memory controller (or another buffer) and the memory chips on the module. In such a buffered system, the memory controller can use different signaling (for example, frequency and voltage values, and point-to-point versus a multi-drop arrangement) with the buffer than the buffer uses with the memory chips.

A dual in-line memory module (DIMM) is an example of a memory module. Multiple modules may be in series and/or parallel. In some memory systems, a memory chip receives signals and repeats them to a next memory chip in a series of two or more memory chips.

Memory controllers have been used in chipset hubs and in a chip that includes a processor core(s). Many computer systems include transmitter and receiver circuitry to allow the system to wirelessly interface with a network.

### BRIEF DESCRIPTION OF THE DRAWINGS

The inventions will be understood more fully from the detailed description given below and from the accompanying drawings of embodiments of the inventions which, however, should not be taken to limit the inventions to the specific embodiments described, but are for explanation and understanding only.

FIGS. 1-9 are each a schematic block diagram representation of stacked chips and a supporting substrate according to some embodiments of the inventions.

FIGS. 10-12 are each a schematic block diagram representation of stacked memory chips according to some embodiments of the inventions.

FIG. 13 is a thermal model of a stacked chip arrangement similar to FIGS. 1 and 7.

FIG. 14 is a schematic block diagram representation of a system including a processor and a memory module according to some embodiments of the inventions.

FIGS. 15-19 are each a block diagram representation of a system including a memory controller according to some embodiments.

### DETAILED DESCRIPTION

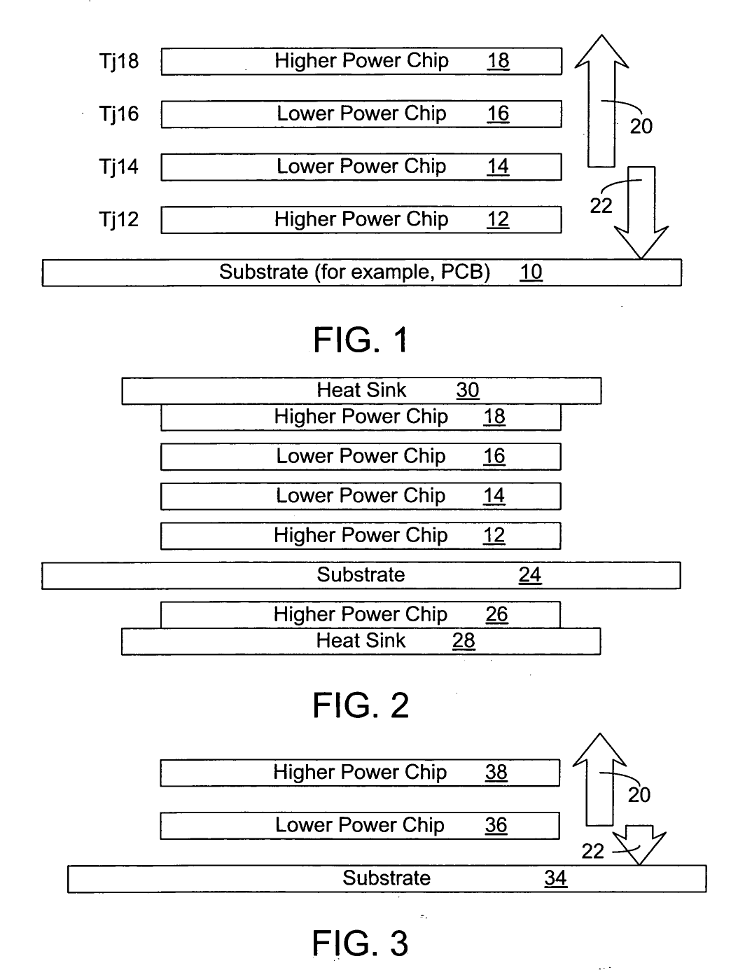

FIG. 1 illustrates a schematic representation of a system including a substrate 10 that supports a stack of chips 12, 14, 16, and 18. For clarity, spaces are shown between chips and between chip 12 and substrate 10, but in actual implementations there would be some structure between them or they would be next to each other. Chips 12-18 could be packaged. Substrate 10 may be, for example, a printed circuit board (PCB), but that is not required. In some embodiments, substrate 10 is a motherboard, which supports a variety of other components. In other embodiments, substrate 10 is a card substrate (such as a memory module substrate or graphics card substrate) that is in turn supported by a motherboard. Arrows 20 and 22 show major directions of heat flow (but certainly not the only directions of heat flow). As can be seen, in the example of FIG. 1, chips 16 and 18 have heat dissipation primarily in the direction of arrow 20. Chip 14 has heat dissipation in the directions of both arrows 22 and 24 and chip 12 has heat dissipation primarily in the direction of arrow 22. Arrows 20 and 22 are not necessarily aligned along a direction of gravity. Temperatures Tj12, Tj14, Tj16, and Tj18 represent temperatures in chips 12, 14, 16, and 18, respectively. Arrows 20 and 22 are just examples. Heat flows from higher to lower temperatures. In practice, the details of arrows 20 and 22 may be different than shown and may change as the temperatures of the chips change. Heat flow can also change as cooling is applied. Chips 12 and 18 are higher power chips and chips 14 and 16 are lower power chips, meaning that chips 12 and 18 ordinarily operate at significantly higher power than do chips 14 and 16. However, because chips 12 and 18 are placed on the outside of the stack, they have greater access to heat dissipation and temperatures Tj12 and Tj18 stay significantly lower than they would be if chips 12 and 18 were on the inside of the stack (as are chips 14 and 16). In the system of FIG. 1, chips 12 and 18 may run at a higher frequency and/or voltage than they would if place on the inside of the stack. Further, since chips 14 and 16 ordinarily operate at lower power, they do not need as much heat dissipation as would higher power chips. In some embodiments, chips 14 and 16 ordinarily operate at the same frequency and/or voltage as chips 12 and 18, although that is not required.

In some embodiments, Tj12, Tj14, Tj16, and Tj18 are about the same temperatures, but in other embodiments Tj12, Tj14, Tj16, and Tj18 are substantially different temperatures. Tj12 may be above or below Tj14 and Tj16. Tj18 may be above or below Tj14 and Tj16. Tj12 may be above or below Tj18. Tj14 may be above or below Tj16. The power that chip 18 ordinarily operates at may be more or less than the power that chip 12 ordinarily operates at. The power that chip 16 ordinarily operates at may be more or less than the power that chip 14 ordinarily operates at.

As used herein, significantly higher power means at least 20% greater. However, in some embodiments, the difference in power may be well greater than 20% and may be even hundreds of percent greater. Examples of power differences includes between 20% and 50%, between 50% and 100%, between 100% and 200%, and greater than 200%.

Various heat dissipation techniques (for example, fans, heat sinks, liquid cooling, etc.) have been developed. The inventions herein are not restricted to any particular of these techniques. In some embodiments, the frequency, voltage, and other characteristics of the chips may be throttled if the temperature or power consumption gets above a threshold.

FIG. 2 shows a system in which a substrate 26 supports chips 12, 14, 16, and 18 on one side substrate and chip 26 on the other side of substrate 26. Chip 26 is shown as being higher power, but that is not required. Chip 26 may operate at higher power than any of chips 12-18. Heat sinks 28 and 30 are shown being attached to chips 26 and 18, respectively. Heat sinks could used in connection the chips of other figures in this disclosure. The heat sinks do not have to be only on the top or bottom of the stacks, but also could be on the sides. The chips in FIG. 2 could be packaged.

FIG. 3 shows a system in which a substrate 30 supports a lower power chip 32 and a higher power chip 34. Arrows 20 and 22 show exemplary heat flow.

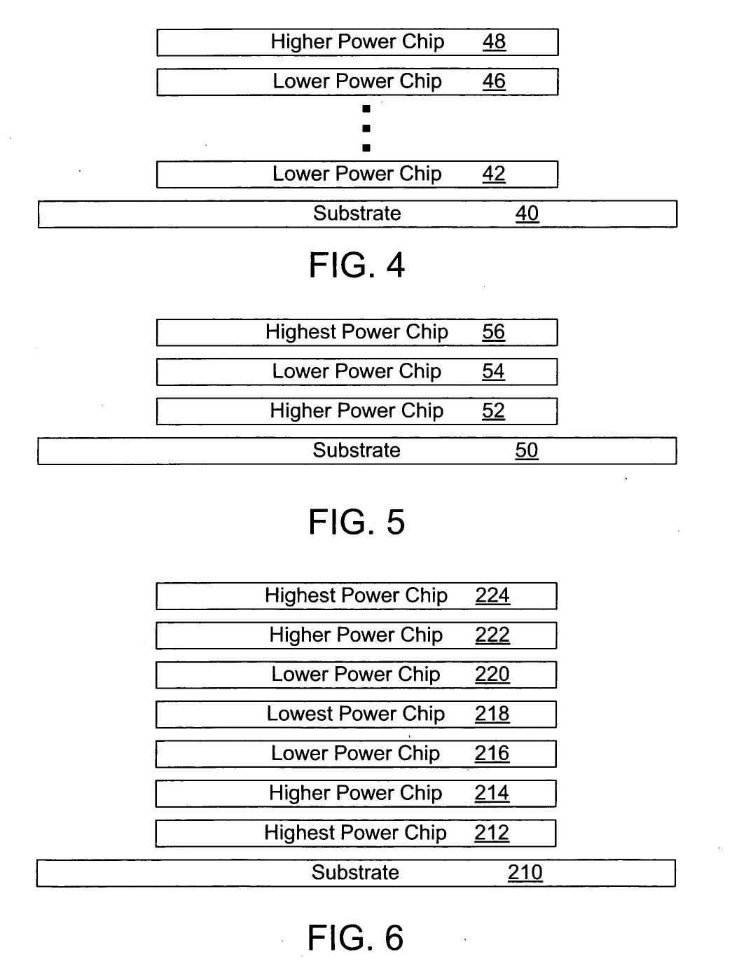

FIG. 4 shows a system in which a substrate 40 supports a lower power chip 42, a lower power chip 46, and a higher power chip 48. Chip 42 may operate at higher, lower, or the same power as chip 46. Chip 42 could be a “higher power” chip. Additional chips may be included between chips 42 and 46. The additional chips may be lower power chips.

FIG. 5 shows a system in which a substrate 50 supports a higher power chip 52, a lower power chip 54, and a highest power chip 56, where chip 56 ordinarily operates at a higher power than does chip 52.

FIG. 6 shows a system with substrate 210 supporting chips 212 (highest power), 214 (higher power), 216 (lower power), chip 218 (lowest power), chip 220 (lower power), chip 222 (higher power), and 224 (highest power). This illustrates that it is desirable to have higher power chips toward the outside of the stack and lower power chips toward the inside, with highest power chips at the outside. Depending on the system, the chip farthest from substrate 210 may receive the best heat dissipation or the chip next to substrate 210 may receive the best heat dissipation. As an alternative to the system of FIG. 6, chip 212 may be a higher power chip and chips 214-chips 220 may be lower power chips. Additional chips may be included in the stack. There are many different possibilities, only a few of which are illustrated in this disclosure. Various kinds of chips could be included in a stack including one or more of the following: a processor chip, a memory chip, a VR chip, a memory buffer chip (see FIG. 16), a communications chip, and others. A processor chip could be in the same stack as a VR chip, a buffer chip, and memory chips, or in a different stack, or not in a stack. There are many possibilities.

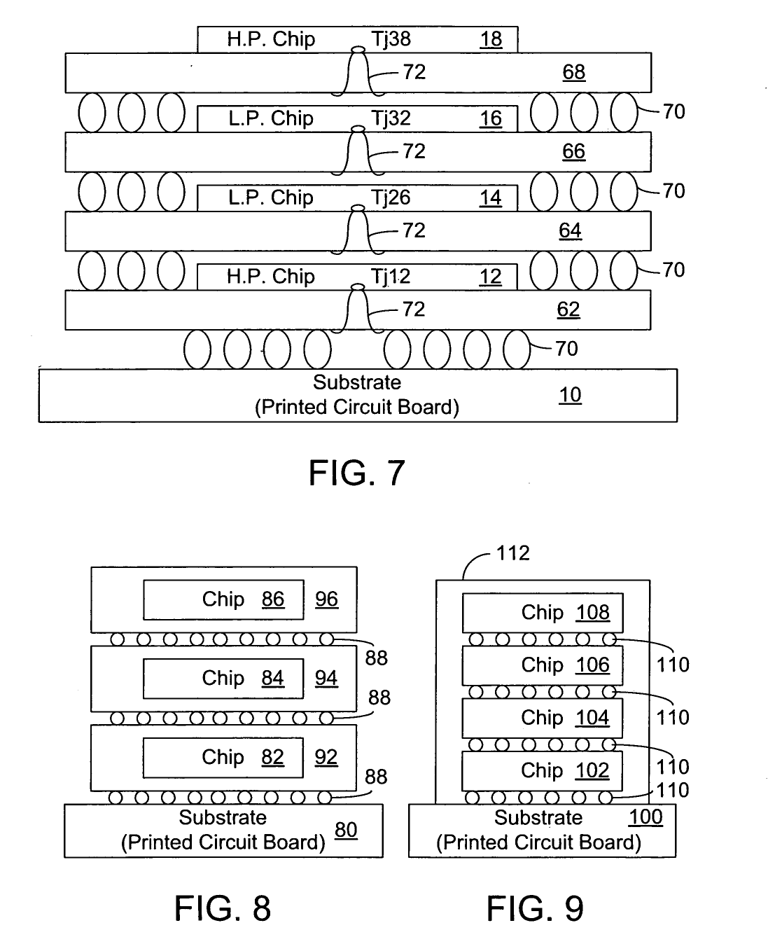

FIG. 7 illustrates a system in which substrate 10 supports stack of chips 12, 14, 16, and 18. As an example, chips 12, 14, 16, and 18 may be memory chips (e.g., flash or DRAM) and substrate 10 may be a memory module substrate, but in other embodiments chips 12, 14, 16, and 18 are not memory chips. Chips 12, 14, 16, and 18 are supported by package supports 62, 64, 66, and 68, which may extend completely around chips 12, 14, 16, and 18 (see FIG. 8). Solder balls 70 join substrates 10 and 62, substrates 62 and 64, substrates 64 and 66, and substrates 66 and 68. In the example of FIG. 7, wire bonds 72 are used of which only a few are visible.

FIG. 8 illustrates a stack with three chips 82, 84, and 86 rather than four as in the case of FIG. 7. FIG. 8 also illustrates substrate packages 92, 94, and 96 completely surrounding chips 82, 84, and 86. Solder balls 88 provide electrical connections. FIG. 8 could have included a stack of more or less than four chips.

FIG. 9 illustrates a substrate 100 supporting a stack of chips 102, 104, 106, and 108 without packages. Solder balls 110 provide electrical connections. FIG. 9 could have including a stack of two, three, or more than four chips.

The inventions are not restricted to any particular type of packaging and signal conduction techniques. For example, the packaging technique and signal conduction may involve wire bond, flip chip, package mold, package substrate, redistribution layers, through silicon vias, and various of components and techniques. Although solder balls are illustrate, different substances may be used to make electrical connections.

The systems of FIGS. 3-9 could include a chip or chips on the other side of the shown substrate. The systems of FIGS. 1-9 could include additional stacks on either side of the substrate and additional chips in the stacks that are shown in the figures. The stacks could include additional chips in the stacks. There could be two higher power chips next to each other. Substrates of FIGS. 1-9 may be, but do not have to be, printed circuit boards. They may be motherboards or some other substrate such as a card.

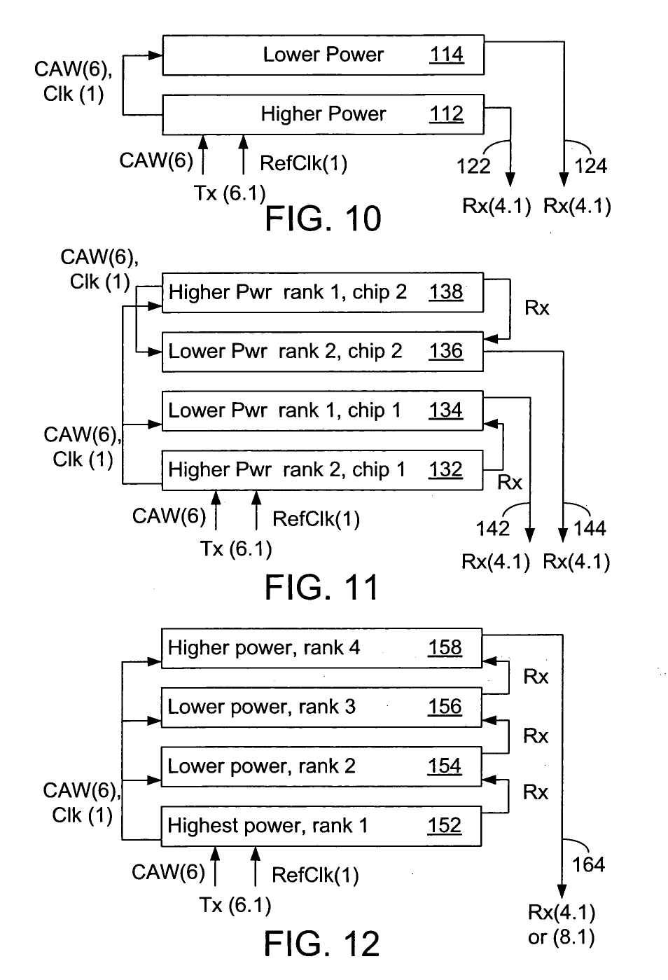

FIGS. 10-12 give examples of chips in a stack. The chips of FIGS. 10-12 may be memory chips including memory cores for storing data. Substrates are not illustrated, but they may be like those of FIGS. 1-9. The inventions are not restricted to the particular examples shown in FIGS. 10-12. The chips may include different details and inter-relationships.

FIG. 10 illustrates a stack of chips 112 and 114. Chip 112 receives command, address, and write data signals (CAW) and clock signals (Clk) which are transmitted (Tx) from another chip (for example, a memory controller). In the example of FIG. 10, there are six lanes of CAW and one lane of Clk so the transmitted signals (Tx) are indicated as 6.1. A lane may be a single conductor with single ended signaling and two conductors with differential signaling. Chip 112 performs the operations of commands directed to chip 112 and also repeats the CAW and clock signals to chip 114. Chip 114 performs the operations specified by commands directed to it. Chip 112 provides four lanes of read data signals and one lane of a read clock signal (Rx 4.1) on conductors 122. Chip 114 provides four lanes of read data signals and one lane of a read clock signal (Rx 4.1) on conductors 124. Because it repeats the CAW and clock signals, chip 112 may be called a repeater chip. As shown below, in some embodiments, the read data from one chip may be directed to another chip, which repeats the read data. Since repeater chips ordinarily operate at higher power, chip 112 could be placed on the outside of the stack similar to chip 34 in FIG. 3. Chips 112 and 114 may be in the same rank, but that is not required.

FIG. 11 shows a stack of chips 132, 134, 136, and 138. In some embodiments, chip 132 is closest to the substrate and chip 138 is farthest from the substrate. In other embodiments, chip 132 farthest. Chip 132 receives six lanes of CAW signals and one lane of a clock signal. Chip 132 acts on the commands that are directed to it and also repeats the CAW and clock signals to chips 134 and 138. Chip 138 in turn repeats the CAW and clock signals to chip 136. Read data signals from a core of chip 132 are provided to chip 134. Read data signals from a core of chip 138 are provided to chip 136. Chip 134 provides read data from its own core and the read data from chip 132 along with a read clock signal to conductors 142. Chip 136 provides read data from its own core and the read data from chip 138 along with a read clock signal to conductors 144. In the example of FIG. 11, chips 132 and 138 are referred to as repeater chips and chips 134 and 136 are referred to as non-repeater chips. Chips 134, 136, and 138 act on commands directed to them. Since the repeater chips ordinarily operate at higher power, chips 132 and 138 would be placed on the outside of the stack as illustrated in FIG. 11. Chip 132 may be the farthest from a PCB substrate like chip 18. In the example of FIG. 11, chips 134 and 138 are part of a first rank (chips accessed together) and chips 132 and 134 are part of a second rank, but this is not required.

FIG. 12 shows a stack of memory chips 152, 154, 156, and 158. In some embodiments, chip 152 is closest to the substrate and chip 158 is farthest from the substrate. In other embodiments, chip 152 is farthest. Chip 152 receives six lanes of CAW signals and one lane of a clock signal. Chip 152 acts on the commands that are directed to it and also repeats the CAW and clock signals to chips 154, 156, and 158. Chips 134, 136, and 138 act on commands directed to them. Read data signals from a core of chip 152 are provided to chip 154. Read data signals from a core of chip 154 are provided to chip 156. Read data signals from a core of chip 156 are provided to chip 158. In addition, chip 154 repeats the read data signals it receives from chip 152 to chip 156, and chip 156 repeats the read data signals it receives from chip 154 to chip 158. Chip 158 provides four lanes of read data signals and one lanes of read clock signals on conductors 164. (In other embodiments, conductors 164 may carry eight lanes of read data and one or two lanes of clock signals.) Chip 152 ordinarily operates at higher power than chips 154, 156, and 158 and may be farthest from a PCB substrate like chip 18. Chip 158 may ordinarily operate at a higher power than chips 154 and 156 or at about the same power. Chip 154 may ordinarily operate at a higher or lower power than chip 156 or at the same power. Chips 152, 154, 156, and 158 may each be in a different rank, but this is not required.

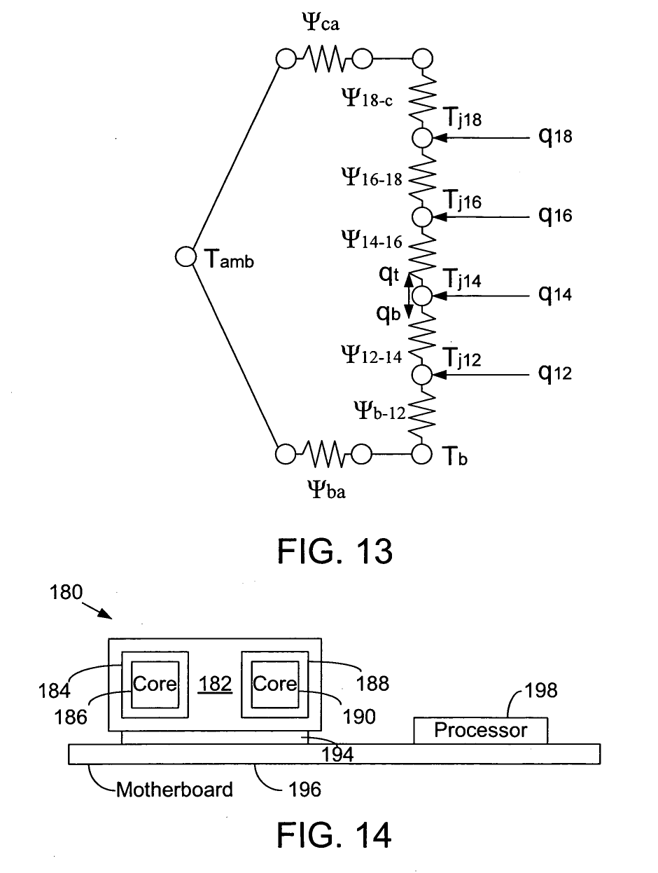

FIG. 13 illustrates a heat flow diagram in which Tj12, Tj14, Tj16, and Tj18 represent temperatures of chips 12, 14, 16, and 18, respectively, in the stack of FIGS. 1 and 7. Tamb is the ambient temperature and Tb is a temperature of substrate board 10. Symbols q12, q14, q16, and q18 represent power consumed by chips 12, 14, 16, and 18. Symbol qt represents the power consumed in the hottest chip in the direction away from substrate 10 and qb represents the power consumed in the hottest chip in the direction toward substrate 10. In the example of FIG. 13, the hottest chip is shown as being chip 14, but any of the other chips could be hottest depending on the circumstances. Symbol Ψca represents thermal resistance between a case of the chip package and the ambient air. The package case is optional. Symbol Ψ18-c represents thermal resistance between chip 18 and the case; Ψ16-18 represents the thermal resistance between chips 16 and 18; Ψ14-16 represents the thermal resistance between chips 14 and 16; Ψ12-14 represents the thermal resistance between chips 12 and 14; Ψb-12 represents the thermal resistance between substrate 10 and chip 12; and Ψba is the thermal resistance between substrate 10 and the ambient temperature. Merely as an example, Ψ16-18, Ψ14-16, and Ψ12-14 may be about 10 C/W, where C is the temperature in centigrade and W is watts, but they may have other values.

Table 1 shows results of an example of thermal simulations of the model of FIG. 13. However, the inventions are not restricted to the details of Table 1 and other simulations may lead to different results. Table 1 and the details mentioned are merely examples based on current understandings and could include mistakes. Further, the inventions may be used with a wide variety of chips and systems, which is another reason why the simulations have limited usefulness.

TABLE 1
Example results of thermal simulations on stack from FIGS. 1 and 7

| | 12.5% non-uniformity | | 50% non-uniformity | |
|---|---|---|---|---|
| | | Stack of | | Stack of |
| | Conventional | FIG. 7 | Conventional | FIG. 7 |
| q_{average}(W) | 0.49 | 0.49 | 0.49 | 0.49 |
| q₁₂(W) | 0.55125 | 0.55125 | 0.735 | 0.735 |
| q₁₄(W) | 0.42875 | 0.42875 | 0.245 | 0.245 |
| q₁₆(W) | 0.55125 | 0.42875 | 0.735 | 0.245 |
| q₁₈(W) | 0.42875 | 0.55125 | 0.245 | 0.735 |
| Tⱼ₁₂(C) | 109.1 | 108.5 | 111.0 | 108.5 |
| Tⱼ₁₄(C) | 109.5 | 108.9 | 110.0 | 107.4 |
| Tⱼ₁₆(C) | 106.5 | 105.8 | 107.1 | 104.3 |
| Tⱼ₁₈(C) | 99.1 | 99.3 | 98.4 | 99.3 |

In Table 1, “W” is watts and “C” is temperature in centigrade. “Conventional” refers to a stacked system in which higher and lower power chips are interlaced in the following order: substrate, higher power chip, lower power chip, higher power chip, lower power chip. In Table 1, “% non-uniformity” refers to the difference in power consumption between higher and lower power chips. For example, in the two columns under “12.5% non-uniformity,” the difference between the higher and lower chips is 12.5%.

It is believed that based on available packaging technologies, the chip to chip thermal resistance, Ψ16-18, Ψ14-16, and Ψ12-14 (generalized to Ψo) may vary from ˜1 C/W to ˜10 C/W depending on the stacking technology, although the inventions are not limited to these details. The benefit seen in using the stacking techniques of FIGS. 1 and 7 may be ˜1 to 3 C depending on the chip to chip power non-uniformity. Further, the benefit may grow as the DRAM power goes up since temperature rise may scale linearly with power increase. This would imply more benefit with the higher power speed bins on DRAM technology. As an example, at double the average chip power in Table 1 [0.49 W to 0.98 W], the proposed stacking technique of FIGS. 1 and 7 may yield a benefit of ˜2 (111.0-108.5) C=5.0 C over the conventional stacking approach at 50% power non-uniformity. Further, for the case of Ψo˜1 C/W (estimated typical chip stacking technologies), the benefit of the stacking technique of FIGS. 1 and 7 may be lowering of Tjmax by ˜1.0-1.3 C for power non-uniformity up to 50%.

In summary, based on preliminary simulations, the proposed stacking approach may yield lower Tjmax˜1.0 C on one end (Ψo˜1 C/W˜chip stacking) and up to ˜5 C for the other end (Ψo˜10 C/W˜package stacking) for the different DRAM stack architectures, where Tjmax is maximum of all chips temperatures, and Ψo is the thermal resistance between two adjacent chips in the stack. The same approach can be applied to two chip and eight chip stacks as well, the quantified benefit is yet to be determined. In general, the benefit is expected to be greater with eight DRAM stacks than with four DRAM stacks. Other conditions will yield different results.

In some embodiments, the stacked according to the invention have the potential of providing higher performance/Watt for high BW (bandwidth) applications like RMS (recognition, mining, synthesis) workloads demanded by multi and many core CPUs. Effectively, this may be an optimal thermal architecture for multi chip DRAM stacks to provided higher performance/Watt.

In some embodiments, repeater DRAMS can consume ˜13 to 50% extra power than the average chip power in the stack. Putting a higher power inside the stack rather than at the outside of the stack may make the hottest chip in the stack much hotter and more susceptible to performance throttling or always running at a lower frequency than needed. Placing higher power chips on the outside of the stack (as in FIG. 7) may lead to higher bandwidth/watt. For some embodiments, the difference between higher and lower power chips may be much higher than 50%. For example, in a system involving a processor chip and memory chips, the processor chip may run at several times the power than the memory chip.

In some embodiments, the chips include circuits that measure temperature and/or circuits to estimate temperature based on activity per unit time.

FIG. 14 illustrates a system with a memory module 180 including a module substrate 182 supporting a first stack including memory chip 184 having a memory core 186. Another stack includes a memory chip 188 having a memory core 190. Module 180 is inserted into slot 194 which is connected to motherboard 196. A processor chip 198 is also supported by motherboard. The CAW and clock signals of FIGS. 10-12 can be provided directly or indirectly from a memory controller insider or outside processor chip 198. The read data and read clock signals of FIGS. 10-12 can be provided directly or indirectly to the memory controller.

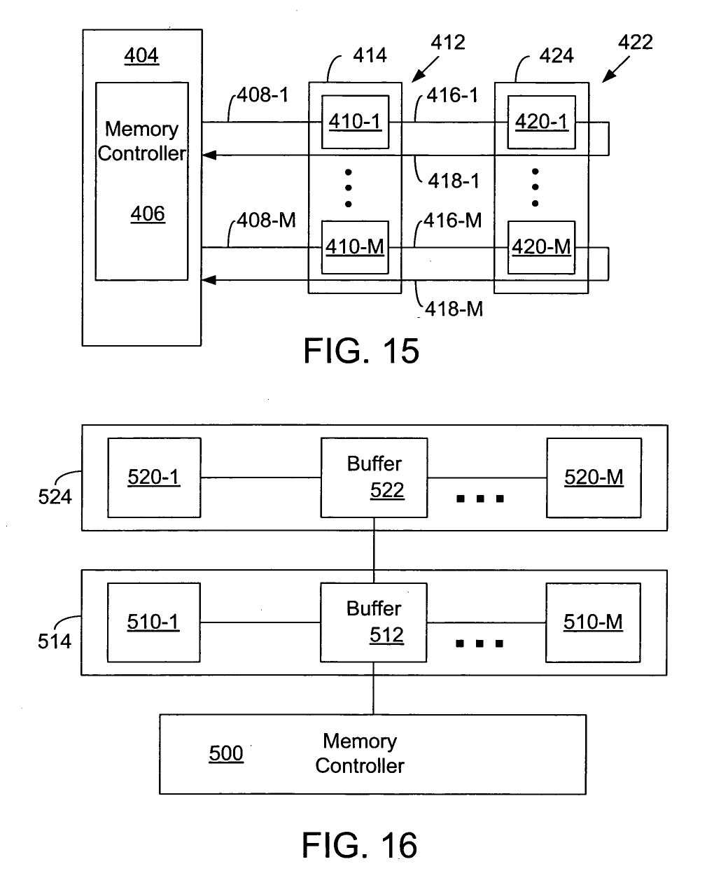

The memory controllers and memory chips described herein may be included in a variety of systems. For example, referring to FIG. 15, chip 404 includes a memory controller 406. Conductors 408-1 . . . 408-M each represent one of more unidirectional or bidirectional interconnects. A memory chip may repeat signals to a next memory chip. For example, the memory chips of stacks 410-1 . . . 410-M repeat some signals to the memory chips of stacks 420-1 . . . 420-M through interconnects 416-1 . . . 416-M. Chips may also repeat to other chips in the same stack. The signals may include command, address, and write data. The signals may also include read data. Read data may be sent directly from the chips of stacks 410-1 . . . 410-M to memory controller 406 through interconnects 408-1 . . . 408-M. However, if read data is repeated from the chips of stacks 410-1 . . . 410-M to the chips of stacks 420-1 . . . 420-M then, in some embodiments, the read data need not be also sent directly from chips 410-1 . . . 410-M to memory controller 406. Read data from the chips of stacks 420-1 . . . 420-M may be sent to memory controller 406 through interconnects 418-1 . . . 418-M. Interconnects 418-1 . . . 418-M are not included in some embodiments. Still referring to FIG. 15, the memory chips of stacks 410-1 . . . 410-M may be on one or both sides of a substrate 414 of a memory module 412. The chips of stacks 420-1 . . . 420-M may be on one or both sides of a substrate 424 of a memory module 422. Alternatively, the chips of stacks 410-1 . . . 410-M may be on the motherboard that supports chip 404 and module 424. In this case, substrate 414 represents a portion of the motherboard.

FIG. 16 illustrates a system in which the chips of stacks 510-1 . . . 510-M are on one or both sides of a memory module substrate 514 and the chips of stacks 520-1 . . . 520-M are on one or both sides of a memory module substrate 524. In some embodiments, memory controller 500 and the chips of stacks 510-1 . . . 510-M communicate to each other through buffer 512, and memory controller 500 and the chips of stacks 520-1 . . . 520-M communicate through buffers 512 and 522. In such a buffered system, the memory controller can use different signaling with the buffer than the buffer uses with the memory chips. Some embodiments may include additional conductors not shown in FIG. 16. A buffer could be part of a stack including memory chips.

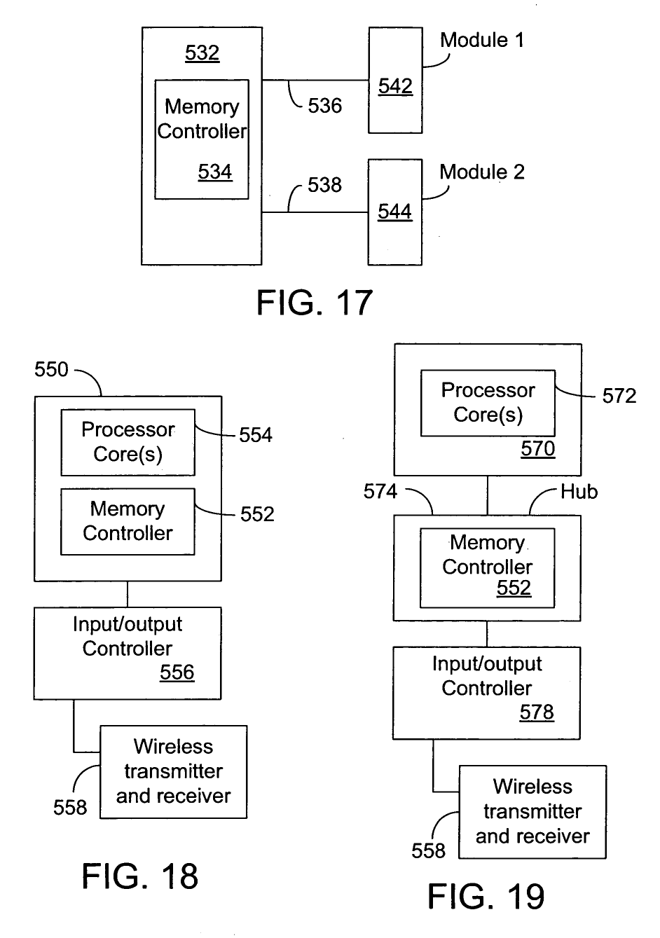

FIG. 17 illustrates first and second channels 536 and 538 coupled to a chip 532 including a memory controller 534. Channels 536 and 538 are coupled to memory modules 542 and 544, respectively, that include chips such as are described herein.

In FIG. 18, a memory controller 552 (which represents any of previously mentioned memory controllers) is included in a chip 550, which also includes one or more processor cores 554. An input/output controller chip 556 is coupled to chip 550 and is also coupled to wireless transmitter and receiver circuitry 558. In FIG. 19, memory controller 552 is included in a chip 574, which may be a hub chip. Chip 574 is coupled between a chip 570 (which includes one or more processor cores 572) and an input/output controller chip 578, which may be a hub chip. Input/output controller chip 578 is coupled to wireless transmitter and receiver circuitry 558.

### ADDITIONAL INFORMATION AND EMBODIMENTS

The inventions are not restricted to any particular signaling techniques or protocols. In actual implementations of the systems of the figures, there would be additional circuitry, control lines, and perhaps interconnects which are not illustrated. When the figures show two blocks connected through conductors, there may be intermediate circuitry that is not illustrated. The shape and relative sizes of the blocks is not intended to relate to actual shapes and relative sizes.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances of “an embodiment,” “one embodiment,” or “some embodiments” are not necessarily all referring to the same embodiments.

When it is said the element “A” is coupled to element “B,” element A may be directly coupled to element B or be indirectly coupled through, for example, element C.

When the specification or claims state that a component, feature, structure, process, or characteristic A “causes” a component, feature, structure, process, or characteristic B, it means that “A” is at least a partial cause of “B” but that there may also be at least one other component, feature, structure, process, or characteristic that assists in causing “B.”

If the specification states a component, feature, structure, process, or characteristic “may”, “might”, or “could” be included, that particular component, feature, structure, process, or characteristic is not required to be included. If the specification or claim refers to “a” or “an” element, that does not mean there is only one of the element.

The inventions are not restricted to the particular details described herein. Indeed, many other variations of the foregoing description and drawings may be made within the scope of the present inventions. Accordingly, it is the following claims including any amendments thereto that define the scope of the inventions.

What is claimed is:

1. A system comprising:
a circuit board;
a first chip; and
a second chip stacked on the first chip, wherein the first chip is coupled between the circuit board and the second chip, and wherein the first chip includes circuitry to repeat commands the first chip receives to the second chip.

2. The system of claim 1, wherein the second chip ordinarily operates at significantly higher power than the first chip.

3. The system of claim 1, further comprising a third chip stacked on the second chip and a fourth chip stacked on the third chip wherein fourth chip ordinarily operates at higher power than the third chip.

4. The system of claim 3, wherein the second and third chips do not repeat commands to other chips.

5. The system of claim 3, wherein the first and fourth chips ordinarily operate at significantly higher power than the second and third chips.

6. The system of claim 1, wherein the first chip repeats address, write data, and clock signals to the second chip.

7. The system of claim 1, wherein the first chip is adjacent to a first substrate and the second chip is adjacent to a second substrate, and wherein there are solder balls between the circuit board and the first substrate, and solder balls between the first substrate and the second substrate.

8. The system of claim 1, wherein the first substrate includes a package in which the first chip is encased and the second substrate includes a package in which the second chip is encased.

9. The system of claim 1, further comprising a motherboard supporting a memory card slot, and wherein the circuit board is part of a memory card that is inserted into the memory card slot.

10. The system of claim 9, wherein the memory card is part of a memory module card and the memory module includes additional memory chips that are not part of the stack of the first and second chips.

11. The system of claim 1, wherein the circuit board is a motherboard.

12. The system of claim 1, further comprising a chip that includes a processor and a memory controller, and wherein the memory controller provides the commands to the first chip.

13. The system of claim 12, further comprising wireless transmitting and receiving circuitry coupled to the chip that includes the processor and the memory controller.

14. The system of claim 1, wherein the first chip is packaged and the package is partially between the circuit board and the first chip.

15. The system of claim 1, further comprising a third chip stacked on the second chip and wherein the first and third chips ordinarily operate at higher power than the second chip, and the third chip ordinarily operates at higher power than the first chip.

16. A system comprising:
a circuit board; and
a first chip, a second chip, a third chip, and a fourth chip in a stacked arrangement;
wherein the first chip is coupled between the circuit board and the second chip; the second chip is coupled between the first chip and the third chip; and the third chip is coupled between the second chip and the fourth chip; and
wherein the first chip and the fourth chip ordinarily operate at significantly higher power than the second chip and third chip.

17. The system of claim 16, further comprising a chip that includes a processor and a memory controller on a different side of the circuit board from the first, second, third, and fourth chips, and wherein the memory controller provides the commands to the first chip, and the wherein the first, second, third, and fourth chips are memory chips.

18. The system of claim 17, wherein the first chip repeats commands from the processor to the second and fourth chips.

19. The system of claim 17, wherein the first chip provides read data to the second chip and the fourth chip provides read data to the third chip, and the second and third chips provide read data to the processor.

20. The system of claim 17, wherein the memory controller provides additional commands to the first chip which the first chip does not repeat to the second chip.

21. The system of claim 16, further comprising wireless transmitting and receiving circuitry coupled to the chip that includes the processor and the memory controller.

22. A system comprising:
a memory module circuit board;
a first memory chip and a second memory chip, wherein the first memory chip is stacked between the circuit board and the second memory chip, and wherein the first memory chip repeats at least some commands to the second memory chip; and
a third memory chip and a fourth memory chip, wherein the third memory chip is stacked between the second memory chip and the fourth memory chip.

23. The system of claim 22, further comprising a chip including a memory controller to provide command, address, and write data signals to the first chip and to receive read data signals from the second and third chips.

24. The system of claim 22, further comprising a chip that includes a processor and a memory controller, and wherein the memory controller provides the commands to the first chip and receives read data signals from the second and third chips.

25. The system of claim 22, wherein the first chip repeats commands from the processor to the second and fourth chips.

26. The system of claim 22, further comprising:
fifth, sixth, seventh and eight stacked memory chips;
wherein the fifth memory chip is coupled between the memory module circuit board and the sixth memory chip, and the seventh memory chip is coupled between the sixth and eighth memory chips.

27. The system of claim 22, wherein one of the chips is one of the following: a memory controller chip, a buffer chip, and a voltage regulation chip.
